(19) United States
(12) Patent Application Publication
(10) Pub. No.: US 2007/0196682 A1
(43) Pub. Date: Aug. 23, 2007

(54) THREE DIMENSIONAL MULTILAYER BARRIER AND METHOD OF MAKING

(76) Inventors: Robert Jan Visser, Menlo Park, CA (US); Lorenza Moro, San Carlos, CA (US); Paul E. Burrows, Kennewick, WA (US); Eric S. Mast, Richland, WA (US); Peter M. Martin, Kennewick, WA (US); Gordon L. Graff, West Richland, WA (US); Mark E. Gross, Pasco, WA (US); Charles C. Bonham, Richland, WA (US); Wendy D. Bennett, Kennewick, WA (US); Michael G. Hall, West Richland, WA (US)

Correspondence Address: DINSMORE & SHOHL LLP, ONE DAYTON CENTRE, ONE SOUTH MAIN STREET, SUITE 1300, DAYTON, OH, 45402-2023, US

(21) Appl. No.: 11/627,583

(22) Filed: Jan. 26, 2007

Related U.S. Application Data
(63) Continuation-in-part of application No. 11/068,356, filed on Feb. 28, 2005.
Application No. 11/068,356 is a division of application No. 09/966,163, filed on Sep. 28, 2001, now Pat. No. 6,866,901.
Application No. 09/966,163 is a continuation-in-part of application No. 09/427,138, filed on Oct. 25, 1999, now Pat. No. 6,522,067.

(51) Int. Cl. B32B 15/00; B05D 1/36; B32B 7/00; C23C 16/00; B05D 3/00

(52) U.S. Cl. 428/594; 427/58; 428/98

(57) ABSTRACT

A three dimensional multilayer barrier. The barrier includes a first barrier continuous layer adjacent to a substrate; a first discontinuous decoupling layer adjacent to the first continuous barrier layer, the first discontinuous decoupling layer having at least two sections; and a second continuous barrier layer adjacent to the first discontinuous decoupling layer, the second barrier forming a wall separating the sections of the first discontinuous decoupling layer. A method of making the three dimensional multilayer barrier is also described.

### BACKGROUND OF THE INVENTION

This application is a continuation-in-part of U.S. application Ser. No. 11/068,356, filed Feb. 28, 2005, which is a Division of U.S. application Ser. No. 09/966,163, filed Sep. 28, 2001, now U.S. Pat. No. 6,866,901, which is a continuation-in-part of U.S. application Ser. No. 09/427,138, filed Oct. 25, 1999, now U.S. Pat. No. 6,522,067, all of which are incorporated herein by reference.

Multilayer, thin film barrier composites having alternating layers of barrier material and polymer material are known. For example, U.S. Pat. No. 6,268,695, entitled “Environmental Barrier Material For Organic Light Emitting Device And Method Of Making,” issued Jul. 31, 2001; U.S. Pat. No. 6,522,067, entitled “Environmental Barrier Material For Organic Light Emitting Device And Method Of Making,” issued Feb. 18, 2003; and U.S. Pat. No. 6,570,325, entitled “Environmental Barrier Material For Organic Light Emitting Device And Method Of Making”, issued May 27, 2003, all of which are incorporated herein by reference, describe encapsulated organic light emitting devices (OLEDs). These multilayer, thin film barrier composites are typically formed by depositing alternating layers of barrier material and decoupling material, such as by vacuum deposition.

Lateral diffusion into the exposed permeable decoupling layers of a multilayer barrier is an issue with respect to use of these structures for encapsulation. Current multilayer barriers are two dimensional structures: planar barrier layers separated by planar decoupling layers. As a result, they are subject to permeation in the plane of the decoupling layer. If the decoupling layers are deposited over the entire surface of the substrate, then the edges of the decoupling layers are exposed to oxygen, moisture, and other contaminants. This potentially allows the moisture, oxygen, or other contaminants to diffuse laterally into an encapsulated environmentally sensitive device from the edge of the composite, as shown in FIG. 1. The multilayer, thin film barrier composite 100 includes a substrate 105 and alternating layers of decoupling material 110 and barrier material 115. The scale of FIG. 1 is greatly expanded in the vertical direction. The area of the substrate 105 will typically vary from a few square centimeters to several square meters. The barrier layers 115 are typically a few hundred Angstroms thick, while the decoupling layers 110 are generally less than ten microns thick. The lateral diffusion rate of moisture and oxygen is finite, and this will eventually compromise the encapsulation. One way to reduce the problem of edge diffusion is to provide long edge diffusion paths. However, this decreases the area of the substrate which is usable for active environmentally sensitive devices. In addition, it only lessens the problem, but does not eliminate it.

Lateral diffusion is also an issue for the use of multilayer barriers on polymer films to create flexible substrates. Practical usage, either roll to roll or sheet based, will require sectioning, or cutting, to yield individual devices, an operation which leads to exposed edges.

Several methods have been proposed to protect the exposed edges. One method involves depositing multilayer barriers as an array of individual areas using methods that form edge sealing structures. An alternative method involves emplacing an edge sealing structure for each individual device subsequent to sectioning. Although both methods can be made to work, the impact of the additional processing steps and inventory logistics has prevented commercialization.

Therefore, there is a need for a multilayer barrier which provides protection against lateral diffusion, and for a method of making the multilayer barrier.

### SUMMARY OF THE INVENTION

The present invention meets that need by providing a three dimensional multilayer barrier comprising a first continuous barrier layer adjacent to a substrate; a first discontinuous decoupling layer adjacent to the first continuous barrier layer, the first discontinuous decoupling layer having at least two sections; and a second continuous barrier layer adjacent to the first discontinuous decoupling layer, the second continuous barrier layer forming a wall separating the sections of the first discontinuous decoupling layer. By adjacent, we mean next to, but not necessarily directly next to. There can be additional layers between two adjacent layers.

Another aspect of the invention relates to a method of making the three dimensional multilayer barrier. The method involves depositing a first continuous barrier layer adjacent to a substrate; depositing a first discontinuous decoupling layer adjacent to the first continuous barrier layer, the first discontinuous decoupling layer having at least two sections; and depositing a second continuous barrier layer adjacent to the first discontinuous decoupling layer, the second continuous barrier layer forming a wall separating the sections of the first discontinuous decoupling layer.

### BRIEF DESCRIPTION OF THE DRAWINGS

FIG. 1 is a cross-section showing lateral diffusion in a prior art two dimensional multilayer barrier.

FIG. 2 is a cross-section showing one embodiment of a three dimensional multilayer barrier of the present invention.

FIG. 3 is a cross-section of one embodiment of a three dimensional multilayer barrier of the present invention.

FIG. 4 is a plan view of the embodiment of FIG. 3.

FIG. 5 is a cross-section of one embodiment of a three dimensional multilayer barrier of the present invention.

FIG. 6 is a plan view of the embodiment of FIG. 5.

FIG. 7 is a diagram of the cross-section and planar views of different shapes for the discontinuous decoupling layer of the present invention.

FIG. 8 is a cross-section of one embodiment of the present invention.

FIG. 9 is a schematic showing the laser cuts on the outside of the calcium patch.

FIG. 10 shows the edge effect for a laser cut at 1360 μm (twice the center to center distance).

FIG. 11 shows the edge effect for a laser cut at 2040 μm (three times the center to center distance).

FIG. 12 shows the edge effect for a laser cut at 2720 μm (four times the center to center distance).

FIG. 13 is a cross-section of one embodiment of an environmentally sensitive device encapsulated by three dimensional multilayer barriers.

FIG. 14 is a cross-section of one embodiment of a three dimensional multilayer barrier and an edge sealed two dimensional barrier.

FIG. 15 is a cross-section of another embodiment of an environmentally sensitive device encapsulated by a three dimensional multilayer barrier.

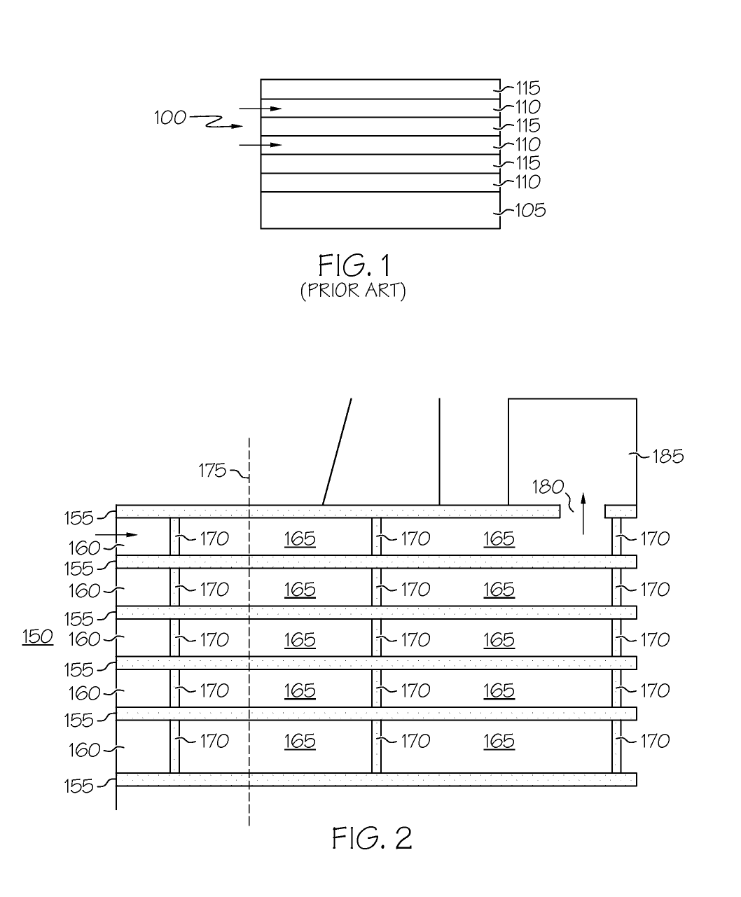

### DETAILED DESCRIPTION OF THE INVENTION

FIG. 2 illustrates the concept of the three dimensional multilayer barrier 150. There are alternating barrier layers 155 and decoupling layers 160. The decoupling layers 160 have sections 165 separated by walls 170. The walls 170 are made of barrier material. Dotted line 175 indicates where a cut could be made that would still result in a wall between the cut edge and the defect 180 in the barrier layer which would prevent the permeants from diffusing to the environmentally sensitive device 185, causing device failure. The walls can be repeated as often as needed across the decoupling layer so that the three dimensional multilayer barrier can be cut while still providing a wall between the permeants and the device.

The three dimensional multilayer barrier shown FIG. 2 is highly simplistic. It depicts simple rectangular cross-sections and perfect staking of cellular decoupling layers. The cells can be polygonal, circular, or other shapes, if desired. The walls do not have to be vertical or have the same thickness; however, they should have sufficient thickness at the thinnest point to provide effective barrier performance. In order to achieve a uniform surface of the resulting multilayer barrier structure, the sections of the decoupling layers can be offset from one another, if desired.

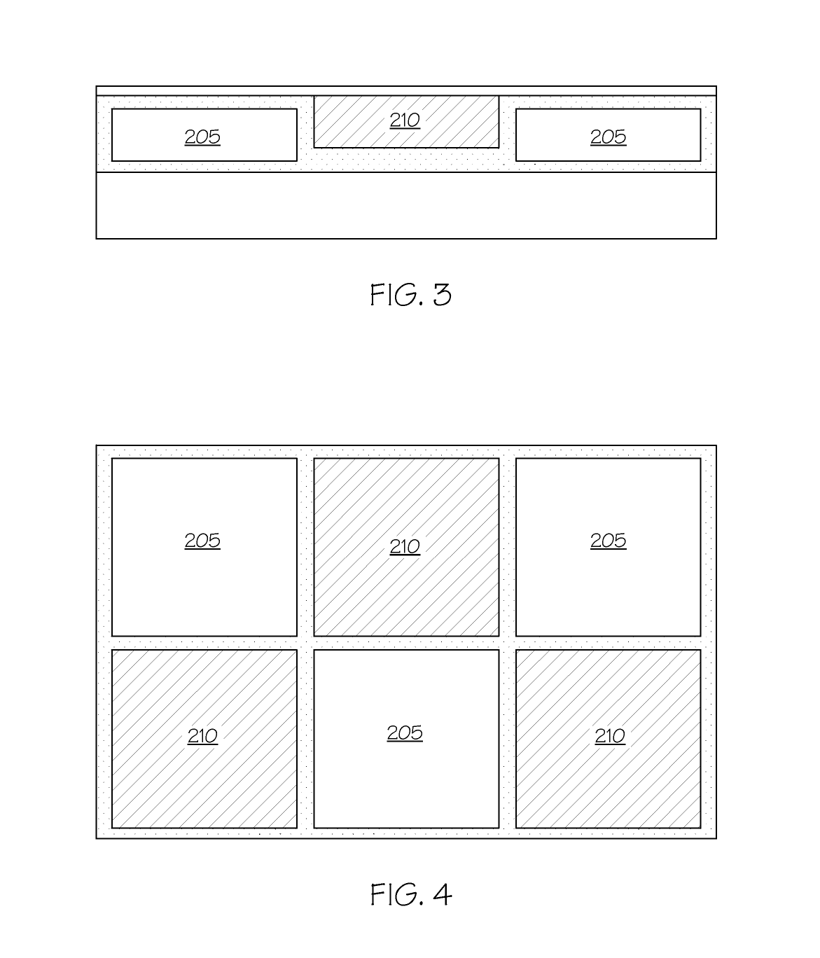

The three dimensional multilayer barrier shown in FIG. 2 can be made using a vacuum process. A planar barrier layer can be deposited by reactive sputtering. The discontinuous decoupling layers can be deposited in a checkerboard pattern through masks with an intervening barrier layer deposition step. A barrier layer is deposited over the second decoupling layer. This process produces a cellular decoupling layer and barrier layer as shown in FIGS. 3 and 4. The sections 210 of the second discontinuous decoupling layer are offset horizontally and vertically from, and are positioned between, the sections 205 of the first discontinuous decoupling layer. This process requires 4 steps (not counting the initial barrier layer deposition) to make a decoupling layer/barrier layer pair in contrast to the two step process currently used (depositing a planar decoupling layer and a planar barrier layer). It also requires a high level of precision mask registration. The resulting structure has vertical walls that are continuous through the thickness of the multilayer structure. This arrangement is undesirable for flexibility, which is an important characteristic of a barrier on a flexible substrate.

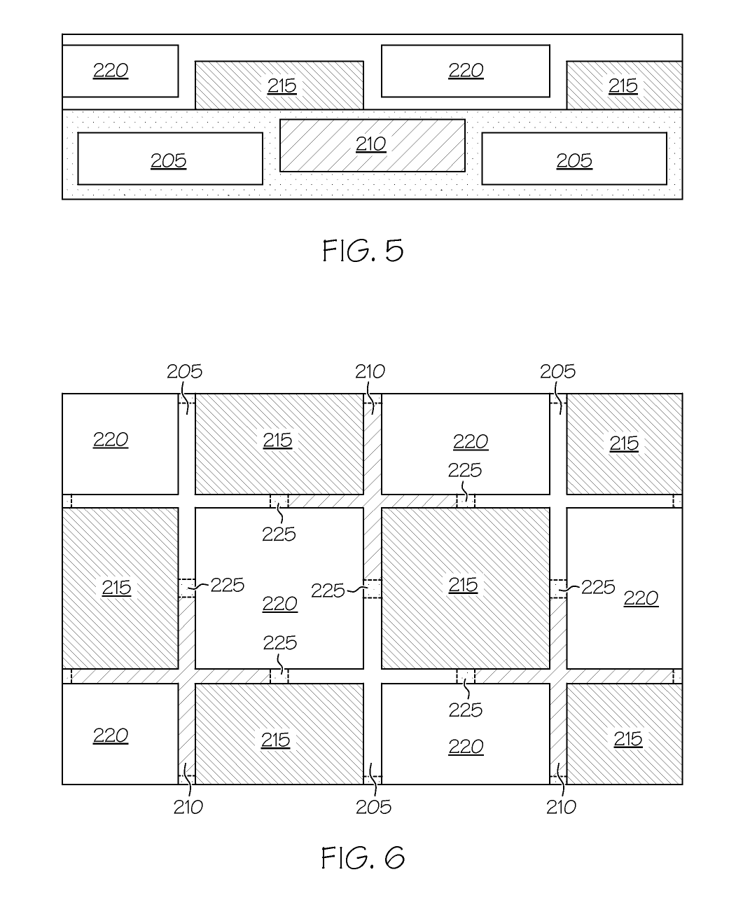

One solution to this situation is to maintain the mask placement within the decoupling layer/barrier layer pair, but shift the relative placement between one decoupling layer/barrier layer pair and the next. For example, shifting mask positions by ½ cell width in both the x and y directions to deposit third and fourth patterned decoupling layers would produce the structure shown in FIGS. 5 and 6. The sections 220 of the fourth discontinuous decoupling layer are offset horizontally and vertically from, and are positioned between, the sections 215 of the third decoupling layer. The sections 215 of the third discontinuous decoupling layer and 220 of the fourth discontinuous decoupling layer are offset horizontally from the sections 205 of the first discontinuous decoupling layer and 210 of the second discontinuous decoupling layer. This structure is characterized by barrier materials forming small vertical “posts” 225 that are continuous through the thickness of the multilayer structure.

The addition of a third decoupling layer/barrier layer pair made by shifting the mask position (e.g., ¼ cell width in both the x and y directions) will result in a structure having 3 decoupling layer/barrier layer pairs free of barrier material based structures that are continuous through the thickness.

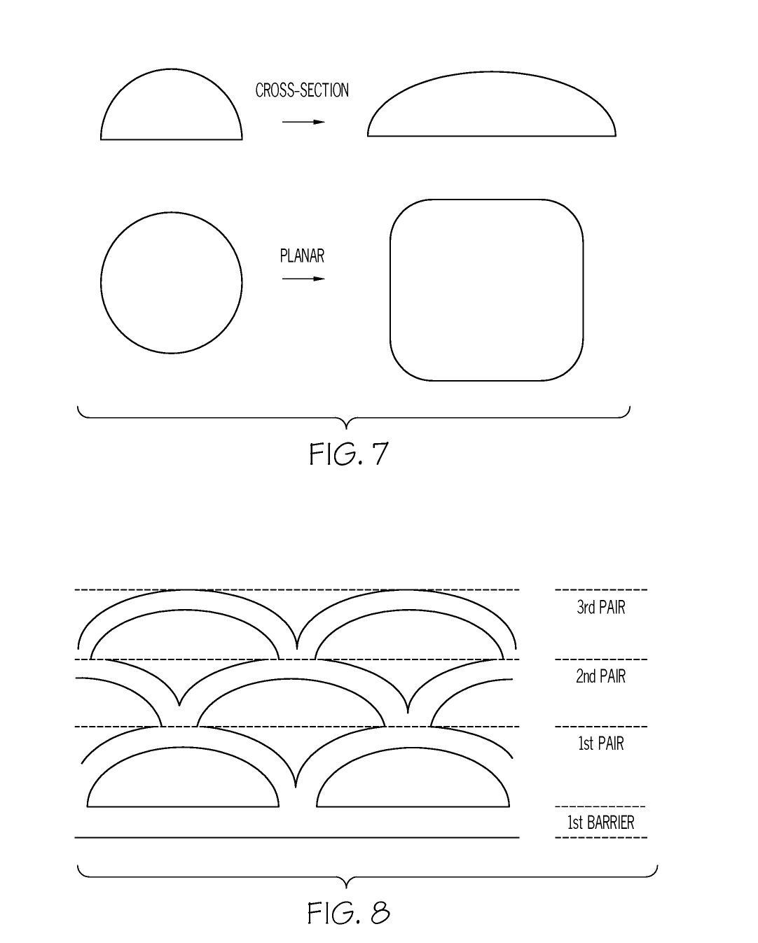

The actual geometry of the deposited decoupling layer will not be as regular as is depicted in the preceding figures. FIG. 7 shows diagrams of the cross-section and planar views of circular and substantially square shapes. With small areas of deposited fluid (in the tens of microns range), the cross-section tends to be semicircular in response to surface tension. With a larger area, the fluid will tend to flatten in response to thickness creating a hydrostatic pressure that overcomes surface tension causing a flattening lateral flow. It would be desirable to have the major percentage of the discontinuous decoupling layer covered by the decoupling material. This favors the square rather than the circular mask opening or the use of overlapping printed drops to create the more nearly square cross-section when larger size decoupling layer units are to be deposited.

A two step vacuum process could be used to make the three dimensional multilayer barrier. The barrier layers can be deposited by reactive sputtering, with alternating patterned discontinuous decoupling layers deposited through masks. A possible cross-section of the resulting barrier structure is shown in FIG. 8. Offsetting the masks between the decoupling layer/barrier layer pairs results in an overlapping pattern.

Various vacuum processes can be used to deposit the barrier layers including, but not limited to, sputtering, reactive sputtering, chemical vapor deposition, plasma enhanced chemical vapor deposition, evaporation, sublimation, electron cyclotron resonance-plasma enhanced vapor deposition (ECR-PECVD), and combinations thereof.

Barrier layers may be made from materials including, but not limited to, metals, metal oxides, metal nitrides, metal carbides, metal oxynitrides, metal oxyborides, and combinations thereof. Metals include, but are not limited to, aluminum, titanium, indium, tin, tantalum, zirconium, niobium, hafnium, yttrium, nickel, tungsten, chromium, zinc, alloys thereof, and combinations thereof. Metal oxides include, but are not limited to, silicon oxide, aluminum oxide, titanium oxide, indium oxide, tin oxide, indium tin oxide, tantalum oxide, zirconium oxide, niobium oxide, hafnium oxide, yttrium oxide, nickel oxide, tungsten oxide, chromium oxide, zinc oxide, and combinations thereof. Metal nitrides include, but are not limited to, aluminum nitride, silicon nitride, boron nitride, germanium nitride, chromium nitride, nickel nitride, and combinations thereof. Metal carbides include, but are not limited to, boron carbide, tungsten carbide, silicon carbide, and combinations thereof. Metal oxynitrides include, but are not limited to, aluminum oxynitride, silicon oxynitride, boron oxynitride, and combinations thereof. Metal oxyborides include, but are not limited to, zirconium oxyboride, titanium oxyboride, and combinations thereof.

The barrier layers can be graded composition barriers, if desired. Suitable graded composition barriers include, but are not limited to, those described in U.S. Pat. No. 7,015,640, which is incorporated herein by reference

Substantially opaque barrier layers can be made from opaque materials including, but not limited to, opaque metals, opaque polymers, opaque ceramics, opaque cermets, and combinations thereof. Opaque cermets include, but are not limited to, zirconium nitride, titanium nitride, hafnium nitride, tantalum nitride, niobium nitride, tungsten disilicide, titanium diboride, zirconium diboride, and combinations thereof.

The decoupling layers can be deposited using vacuum processes, including but not limited to, flash evaporation with in situ polymerization under vacuum, or plasma deposition and polymerization.

Alternatively, the decoupling layers can be made using an atmospheric process. Suitable atmospheric processes include, but are not limited to, spin coating, ink jet printing, screen printing, spraying, or combinations thereof. Ink jet printing is advantageous because it is a non-contact process, which avoids damage and contamination caused by contact with the fragile barrier layers. In addition, it is capable of producing the required feature sizes, and it can achieve the necessary accuracy of registration over multiple deposition steps.

The decoupling layer could be deposited initially as a continuous layer using a process including, but not limited to, spin coating. The decoupling layer could then be divided into sections by a process including, but not limited to, mask etching. Alternatively, the surface of the substrate could be masked prior to the spincoating or other deposition process.

Decoupling layers can be made from materials including, but not limited to, organic polymers, inorganic polymers, organometallic polymers, hybrid organic/inorganic polymer systems, and silicates. Organic polymers include, but are not limited to, (meth)acrylates, urethanes, polyamides, polyimides, polybutylenes, isobutylene isoprene, polyolefins, epoxies, parylene, benzocyclobutadiene, polynorbornenes, polyarylethers, polycarbonate, alkyds, polyaniline, ethylene vinyl acetate, and ethylene acrylic acid. Inorganic polymers include, but are not limited to, silicones, polyphosphazenes, polysilazane, polycarbosilane, polycarborane, carborane siloxanes, polysilanes, phosphonitriles, sulfur nitride polymers, and siloxanes. Organometallic polymers include, but are not limited to, organometallic polymers of main group metals, transition metals and lanthanide/actinide metals (for example, polymetallocenylenes such as polyferrocene and polyruthenocene). Hybrid organic/inorganic polymer systems include, but are not limited to, organically modified silicates, ceramers, preceramic polymers, polyimide-silica hybrids, (meth)acrylate-silica hybrids, polydimethylsiloxane-silica hybrids.

Tests were performed to evaluate the three dimensional multilayer barrier of the present invention using the calcium test. The calcium test is described in Nisato et al., “Thin Film Encapsulation for OLEDs: Evaluation of Multi-layer Barriers using the Ca Test,” SID 03 Digest, 2003, p. 550-553, which is incorporated herein by reference.

A three dimensional multilayer barrier comprised of an initial barrier layer of 400 Å with 4 decoupling layer/barrier layer pairs (0.5 μm of acrylate polymer and 400 Å of aluminum oxide) was formed over the calcium on a glass substrate. The mask used to form the decoupling layer had 480 μm diameter holes with a 200 μm distance between the holes, resulting in a 680 μm distance from the center of one hole to the center of the next.

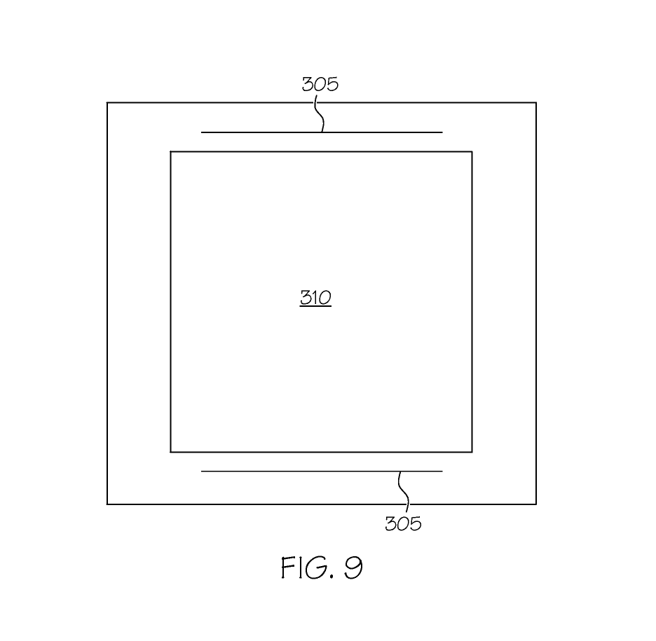

Laser cuts 305 were made outside the calcium region 310 on 2 opposing sides, as shown schematically in FIG. 9. The cuts were made at distances of 1360 μm (twice the center to center distance), 2040 μm (three times the center to center distance), and 2720 μm (four times the center to center distance). The barrier degradation was observed along the cut edges. The samples were subjected to a temperature of 60° C. and 90% relative humidity.

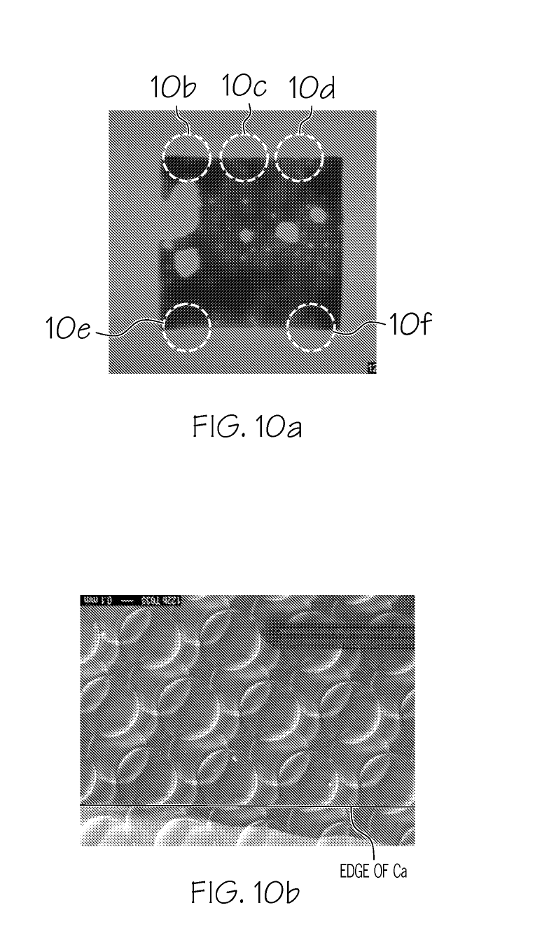

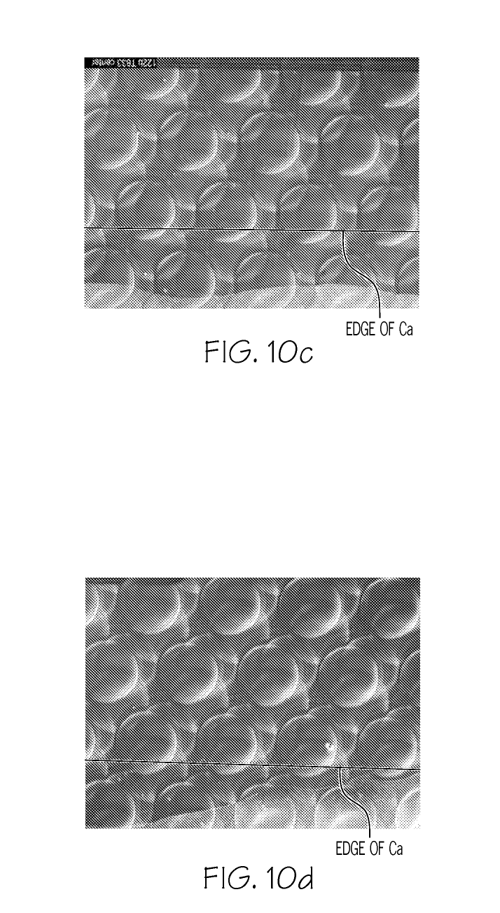

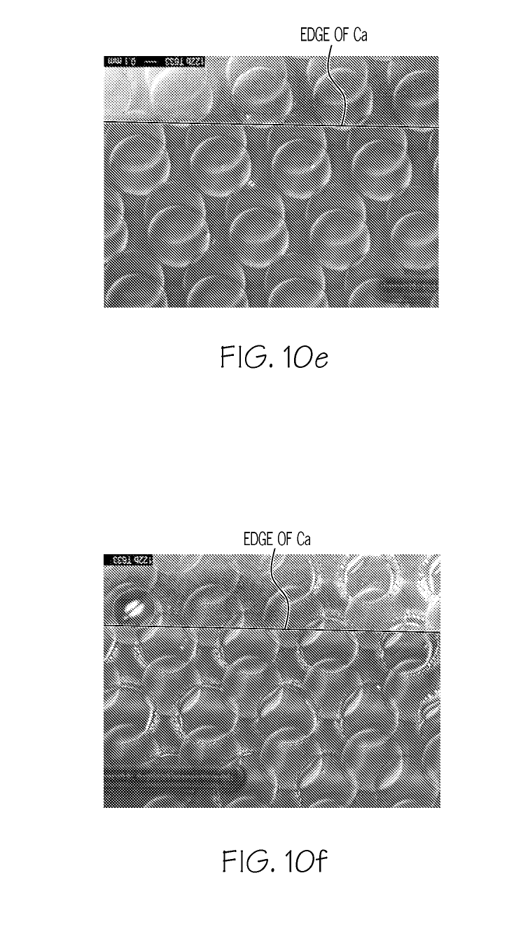

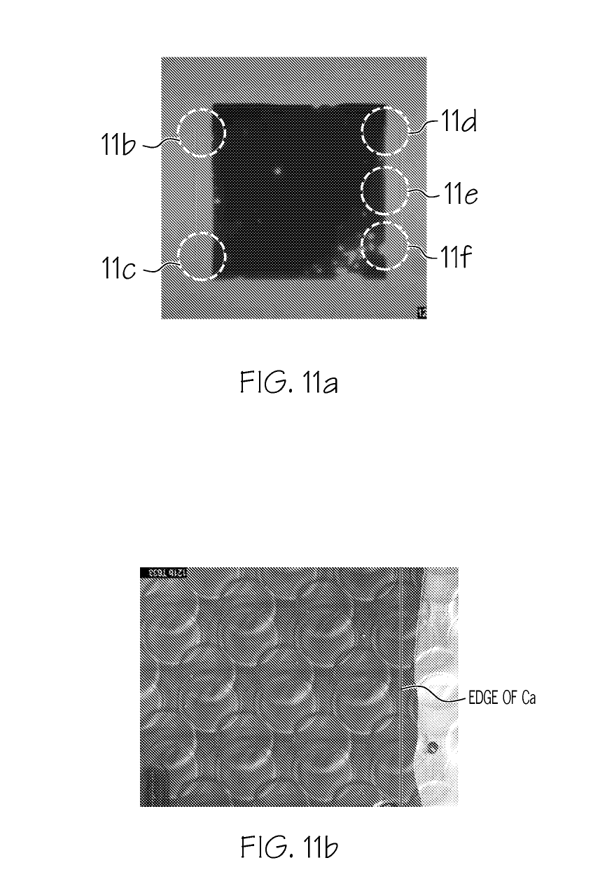

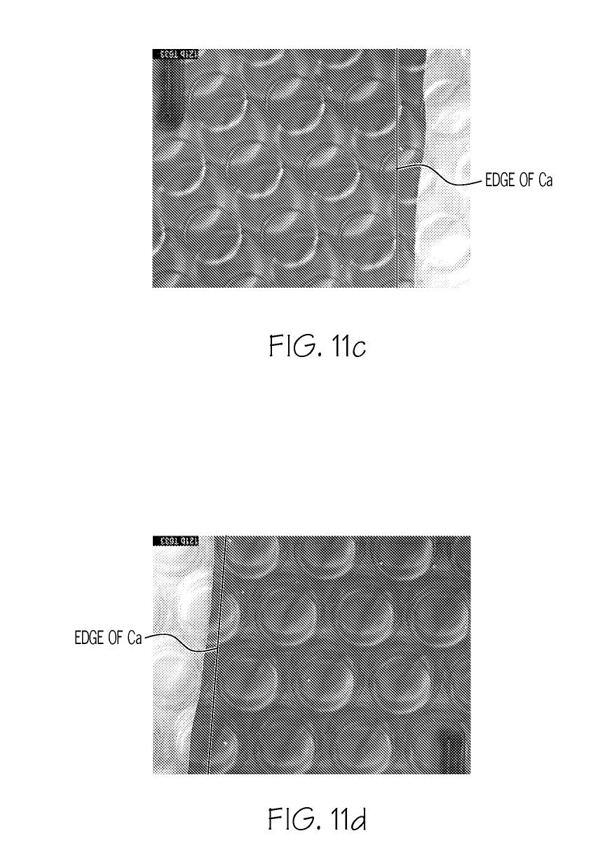

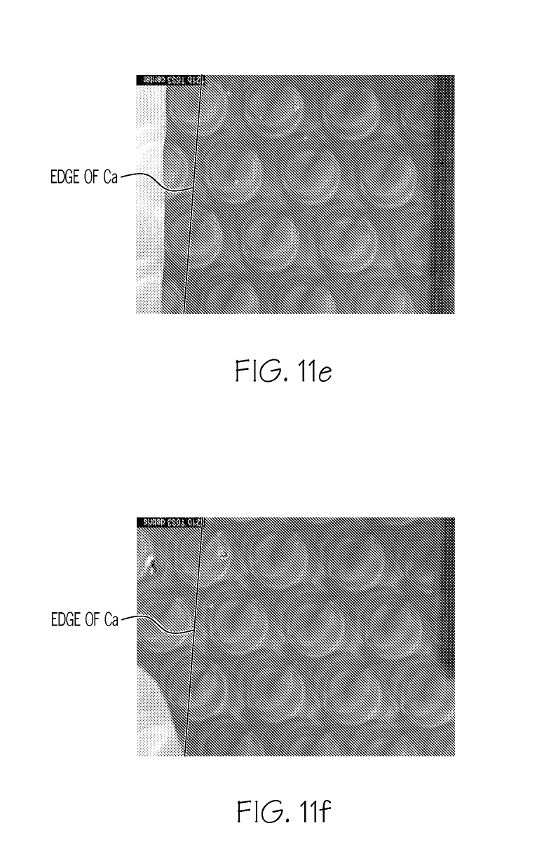

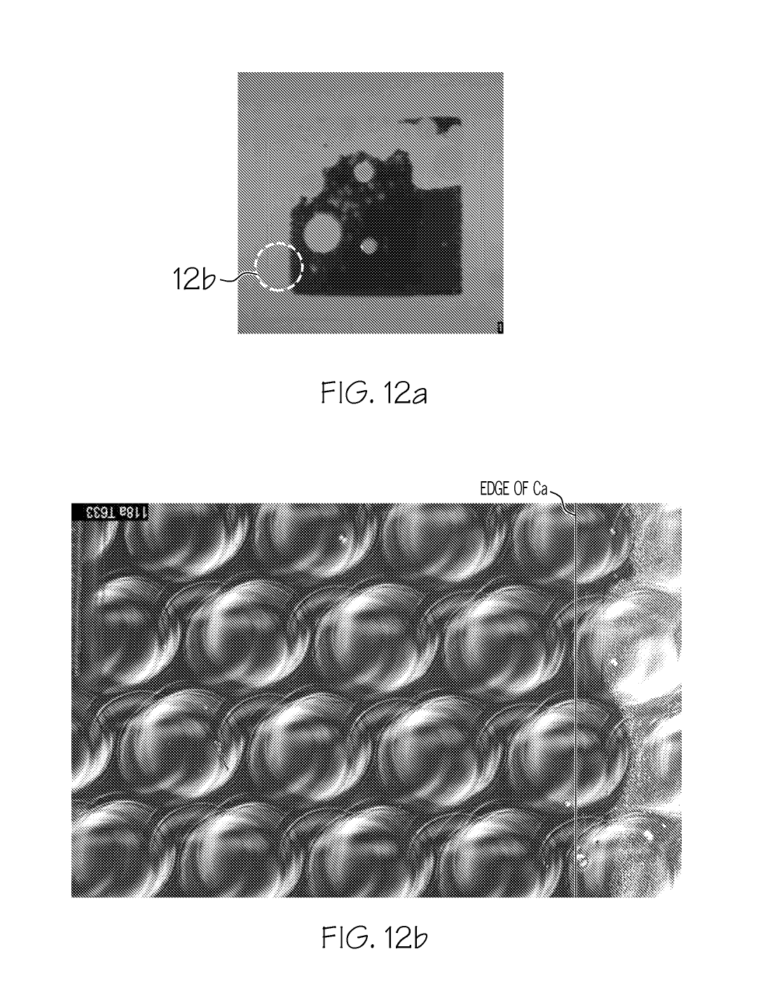

No edge effect was seen for any of the samples after 96 hrs. After 633 hrs, an edge effect was seen for the samples cut at 1360 μm (twice the center to center distance), as shown in FIG. 10. A possible minimal edge effect was seen for the samples cut at 2040 μm (three times the center to center distance), as shown in FIG. 11. No edge effect was seen for the samples cut at 2720 μm (four times the center to center distance), as shown in FIG. 12. Although there were many defects in all the samples, these were not caused by the cuts, but by debris in the coating, or excessive handling, or some other reason.

The results from the calcium test indicate that these samples have an oxygen transmission rate (OTR) of less than 0.005 cc/m²/day at 23° C. and 0% relative humidity, and less than 0.005 cc/m²/day at 38° C. and 90% relative humidity. The results also indicate that the samples have a water vapor transmission rate (WVTR) of less than 0.005 gm/m²/day at 38° C. and 100% relative humidity. These values are well below the detection limits of current industrial instrumentation used for permeation measurements (Mocon OxTran 2/20L and Permatran) (measured according to ASTM F 1927-98 and ASTM F 1249-90, respectively).

The barrier layers could be deposited as continuous layers across the entire substrate. This will be the most common situation. However, the barrier layers could also be deposited over only a portion of the substrate using a mask, for example, in order to form an array of devices in which each device is individually encapsulated. In this case, the barrier layer should be deposited over at least two sections of the discontinuous decoupling layer so that at least one wall of barrier material will be formed separating the sections of the discontinuous decoupling layer.

A continuous layer will not have any intentionally formed gaps in coverage. A discontinuous layer will have intentionally formed gaps in coverage.

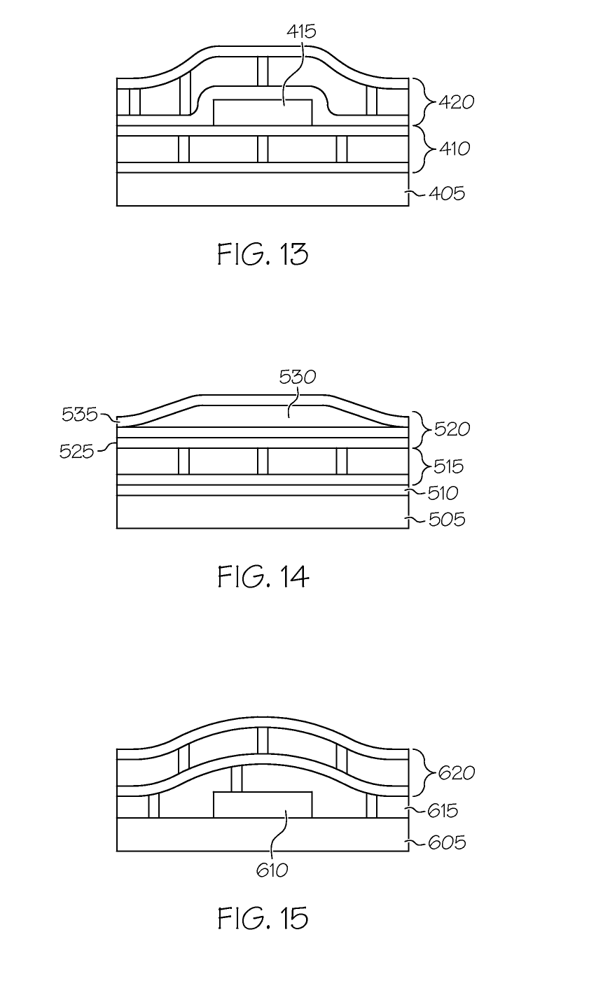

The three dimensional multilayer barrier of the present invention can be used to encapsulate environmentally sensitive devices without the need to edge seal the barrier structures, as well as being used as barriers on flexible substrates. The three dimensional multilayer barrier of the present invention can be included on either side or both sides of the environmentally sensitive device, as desired. As shown in FIG. 13, a first three dimensional multilayer barrier 410 could be formed on a substrate 405. An environmentally sensitive device 415 could then be placed adjacent to the first three dimensional multilayer barrier 410. A second three dimensional multilayer barrier 420 could then be placed adjacent to the environmentally sensitive device 415 on the side opposite the first three dimensional multilayer barrier 410. The environmentally sensitive device 415 would be encapsulated between the first and second three dimensional multilayer barriers 410, 420.

Optionally, a conventional two dimensional barrier could be combined with the three dimensional multilayer barrier. For example, as shown in FIG. 14, there could be a three dimensional multilayer barrier 515 and a two dimensional barrier 520. Alternatively, there could be a two dimensional barrier and a three dimensional multilayer barrier on top of that. The two dimensional barrier 520 could have an edge seal in which two barrier layers 525 and 535 enclose and form a seal around a decoupling layer 530 positioned between them.

If desired, one or more functional layers could be deposited before and/or after depositing the three dimensional multilayer barrier, and/or the two dimensional barrier. There could be functional layers on either or both sides of the environmentally sensitive device. FIG. 14 shows a functional layer 510 between the substrate 505 and the three dimensional multilayer barrier 515. The functional layers can include, but are not limited to, planarizing layers, barrier layers, hard coats, scratch resistant coatings, thermal coefficient of expansion (TCE) matching coatings, plasma protection layers, coatings which modify optical properties, such as anti-reflection, viewing angle limiting, etc., adhesion enhancement, and the like.

In addition, a discontinuous decoupling layer could be deposited before the first continuous barrier layer is deposited, if desired. This could be useful in encapsulating environmentally sensitive devices which have continuous cathodes as the top layer, including, but not limited to, active matrix devices and backlights. As shown in FIG. 15, an environmentally sensitive device 610 is positioned on substrate 605. A discontinuous decoupling layer 615 is deposited before the three dimensional multilayer barrier 620.

While certain representative embodiments and details have been shown for purposes of illustrating the invention, it will be apparent to those skilled in the art that various changes in the compositions and methods disclosed herein may be made without departing from the scope of the invention, which is defined in the appended claims.

What is claimed is:

1. A three dimensional multilayer barrier comprising:
a first continuous barrier layer adjacent to a substrate;
a discontinuous decoupling layer adjacent to the first continuous barrier layer, the discontinuous decoupling layer having at least two sections; and
a second continuous barrier layer adjacent to the discontinuous decoupling layer, the second continuous barrier layer forming a wall separating the sections of the discontinuous decoupling layer.

2. The three dimensional multilayer barrier of claim 1 further comprising:
a second discontinuous decoupling layer adjacent to the second continuous barrier layer, the second discontinuous decoupling layer having at least two sections; and
a third continuous barrier layer adjacent to the second discontinuous decoupling layer, the third continuous barrier layer forming a wall separating the sections of the second discontinuous decoupling layers.

3. The three dimensional multilayer barrier of claim 2 wherein the sections of the second discontinuous decoupling layer are offset horizontally from the sections of the first discontinuous decoupling layer.

4. The three dimensional multilayer barrier of claim 2 wherein the sections of the second discontinuous decoupling layer are positioned between the sections of the first discontinuous decoupling layer.

5. The three dimensional multilayer barrier of claim 4 further comprising:
a third discontinuous decoupling layer adjacent to the third continuous barrier layer, the third discontinuous decoupling layer having at least two sections; and
a fourth continuous barrier layer adjacent to the first discontinuous decoupling layer, the fourth continuous barrier forming a wall separating the sections of the third discontinuous decoupling layer;
a fourth discontinuous decoupling layer adjacent to the fourth continuous barrier layer, the fourth discontinuous decoupling layer having at least two sections; and
a fifth continuous barrier layer adjacent to the fourth discontinuous decoupling layer, the fifth continuous barrier layer forming a wall separating the sections of the fourth discontinuous decoupling layers.

6. The three dimensional multilayer barrier of claim 5 wherein the sections of the third discontinuous decoupling layer are offset horizontally from the sections of the second discontinuous decoupling layer.

7. The three dimensional multilayer barrier of claim 5 wherein the sections of the fourth discontinuous decoupling layer are offset horizontally from the sections of the third discontinuous decoupling layer.

8. The three dimensional multilayer barrier of claim 5 wherein the sections of the fourth discontinuous decoupling layer are positioned between the sections of the third discontinuous decoupling layer.

9. The three dimensional multilayer barrier of claim 1 wherein the first or second barrier layer is made of a material selected from metals, metal oxides, metal nitrides, metal carbides, metal oxynitrides, metal oxyborides, or combinations thereof.

10. The three dimensional multilayer barrier of claim 1 wherein the first decoupling layer is made of a material selected from organic polymers, inorganic polymers, organometallic polymers, hybrid organic/inorganic polymer systems, silicates, or combinations thereof.

11. The three dimensional multilayer barrier of claim 1 wherein the oxygen transmission rate through the three dimensional multilayer barrier is less than 0.005 cc/m²/day at 23° C. and 0% relative humidity.

12. The three dimensional multilayer barrier of claim 1 wherein the oxygen transmission rate through the three dimensional multilayer barrier is less than 0.005 cc/m²/day at 38° C. and 90% relative humidity.

13. The three dimensional multilayer barrier of claim 1 wherein the water vapor transmission rate through the three dimensional multilayer barrier is less than 0.005 gm/m²/day at 38° C. and 100% relative humidity.

14. The three dimensional multilayer barrier of claim 1 further comprising a discontinuous decoupling layer between the substrate and the first continuous barrier layer.

15. The three dimensional multilayer barrier of claim 1 further comprising an environmentally sensitive device between the substrate and the first continuous barrier layer.

16. The three dimensional multilayer barrier of claim 15 further comprising a second three dimensional multilayer barrier between the substrate and the environmentally sensitive device, the second three dimensional multilayer barrier comprising:
a first continuous barrier layer adjacent to the substrate;
a discontinuous decoupling layer adjacent to the first continuous barrier layer, the discontinuous decoupling layer having at least two sections; and
a second continuous barrier layer adjacent to the discontinuous layer, the second continuous barrier layer forming a wall separating the sections of the discontinuous decoupling layers, wherein the environmentally sensitive device is encapsulated between the three dimensional multilayer barrier and the second three dimensional multilayer barrier.

17. The three dimensional multilayer barrier of claim 1 further comprising a functional layer.

18. The three dimensional multilayer barrier of claim 1 further comprising at least one two dimensional barrier stack comprising at least two continuous barrier layers and at least one continuous decoupling layer positioned between the at least two continuous barrier layers, the at least two continuous barrier layers enclosing and forming a seal around the at least one continuous decoupling layer.

19. The three dimensional multilayer barrier of claim 18 wherein the at least one two dimensional barrier stack is positioned between the substrate and the first continuous barrier layer of the three dimensional multilayer barrier.

20. The three dimensional multilayer barrier of claim 18 wherein the at least one two dimensional barrier stack is positioned adjacent the second continuous barrier layer of the three dimensional multilayer barrier on a side opposite the substrate.

21. A method of making a three dimensional multilayer barrier comprising:
depositing a first continuous barrier layer adjacent to a substrate;
depositing a first discontinuous decoupling layer adjacent to the first continuous barrier layer, the first discontinuous decoupling layer having at least two sections;
depositing a second continuous barrier layer adjacent to the first discontinuous decoupling layer, the second continuous barrier layer forming a wall separating the sections of the first discontinuous decoupling layer.

22. The method of claim 21 further comprising:
depositing a second discontinuous decoupling layer adjacent to the second continuous barrier layer, the second discontinuous decoupling layer having at least two sections; and
depositing a third continuous barrier layer adjacent to the second discontinuous decoupling layer, the third continuous barrier layer forming a wall separating the sections of the second discontinuous decoupling layer.

23. The method of claim 22 wherein the sections of the second discontinuous decoupling layer are offset horizontally from the sections of the first discontinuous decoupling layer.

24. The method of claim 22 wherein the sections of the second discontinuous decoupling layer are positioned between the sections of the first discontinuous decoupling layer.

25. The method of claim 21 wherein the first or second continuous barrier layer is deposited using a vacuum process.

26. The method of claim 25 wherein the vacuum process is selected from sputtering, reactive sputtering, chemical vapor deposition, plasma enhanced chemical vapor deposition, evaporation, sublimation, electron cyclotron resonance-plasma enhanced vapor deposition (ECR-PECVD), and combinations thereof.

27. The method of claim 21 wherein the first discontinuous decoupling layer is deposited using a vacuum process.

28. The method of claim 27 wherein the vacuum process is selected from flash evaporation with in situ polymerization, or plasma deposition and polymerization, or combinations thereof.

29. The method of claim 21 wherein the first discontinuous decoupling layer is deposited using an atmospheric process.

30. The method of claim 29 wherein the atmospheric process is selected from spin coating, ink jet printing, screen printing, spraying, or combinations thereof.

31. The method of claim 21 wherein the first discontinuous decoupling layer is deposited using a mask.
